(19) United States
(12) Patent Application Publication
(10) Pub. No.: US 2023/0422559 A1
(43) Pub. Date: Dec. 28, 2023

(54) DISPLAY APPARATUS

(71) Applicant: Samsung Display Co., Ltd., Yongin-si (KR)

(72) Inventors: Kwangmin Kim, Yongin-si (KR); Wonkyu Kwak, Yongin-si (KR); Kiwook Kim, Yongin-si (KR); Doyeon Hwang, Yongin-si (KR)

(21) Appl. No.: 18/320,069

(22) Filed: May 18, 2023

(30) Foreign Application Priority Data
Jun. 24, 2022 (KR) 10-2022-0077807

(51) Int. Cl. H10K 59/122; H10K 59/131

(52) U.S. Cl. CPC H10K 59/122; H10K 59/1315

(57) ABSTRACT

A display apparatus includes: a first pixel electrode and a second pixel electrode spaced apart from each other on a substrate; a pixel defining layer having a first opening exposing a central portion of the first pixel electrode and a second opening exposing a central portion of the second pixel electrode; a separator above the pixel defining layer and, in a plan view, between the first opening and the second opening; a connection electrode between the pixel defining layer and the separator; a first intermediate layer on the first pixel electrode; a second intermediate layer on the second pixel electrode and spaced apart from the first intermediate layer; a first counter electrode on the first intermediate layer and electrically connected to the connection electrode; and a second counter electrode on the second intermediate layer, spaced apart from the first counter electrode, and electrically connected to the connection electrode.

### CROSS-REFERENCE TO RELATED APPLICATION

The present application claims priority to and the benefit of Korean Patent Application No. 10-2022-0077807, filed on Jun. 24, 2022, in the Korean Intellectual Property Office, the entire disclosure of which is incorporated herein by reference.

### BACKGROUND

### 1. Field

Aspects of one or more embodiments relate to a display apparatus.

### 2. Description of the Related Art

Some layers of a display apparatus, for example, an intermediate layer between a pixel electrode and a counter electrode, may be commonly provided in a plurality of display elements. Accordingly, when a current is supplied to one display element, the current may be supplied to other neighboring display elements through the layers commonly provided in the display elements, and thus, the color purity of the display apparatus may be deteriorated. To address this matter, a display apparatus may include a separator and the like.

The above information disclosed in this Background section is only for enhancement of understanding of the background and therefore the information discussed in this Background section does not necessarily constitute prior art.

### SUMMARY

Aspects of one or more embodiments relate to display apparatuses, and for example, to display apparatuses which may reduce a leakage current and effectively transmit electrical signals to a plurality of counter electrodes.

In a display apparatus according to the related art, in a process of transmitting electrical signals to a plurality of counter electrodes, the electrical signals may not be effectively transmitted to the counter electrodes.

A display apparatus according to some embodiments may reduce a leakage current and also effectively transmit electrical signals to a plurality of counter electrodes. However, such characteristics are merely examples of some characteristics according to some embodiments, and the scope of embodiments according to the present disclosure is not limited thereby.

Additional aspects will be set forth in part in the description which follows and, in part, will be apparent from the description, or may be learned by practice of the presented embodiments of the disclosure.

According to some embodiments of the present disclosure, a display apparatus includes a first pixel electrode and a second pixel electrode spaced apart from each other on a substrate, a pixel defining layer having a first opening exposing a central portion of the first pixel electrode and a second opening exposing a central portion of the second pixel electrode, a separator above the pixel defining layer, and when viewed from a direction perpendicular to the substrate (e.g., in the plan view), spaced between the first opening and the second opening, a connection electrode interposed between the pixel defining layer and the separator, a first intermediate layer on the first pixel electrode, a second intermediate layer on the second pixel electrode and spaced apart from the first intermediate layer, a first counter electrode on the first intermediate layer and electrically connected to the connection electrode, and a second counter electrode on the second intermediate layer, spaced apart from the first counter electrode, and electrically connected to the connection electrode.

According to some embodiments, when viewed from the direction perpendicular to the substrate (e.g., in a plan view), the width of a portion of the first counter electrode overlapping the connection electrode may be greater than the width of a portion of the first intermediate layer overlapping the connection electrode.

According to some embodiments, the connection electrode may be in contact with the first counter electrode.

According to some embodiments, when viewed from the direction perpendicular to the substrate (e.g., in the plan view), the width of a portion of the second counter electrode overlapping the connection electrode may be greater than the width of a portion of the second intermediate layer overlapping the connection electrode.

According to some embodiments, the connection electrode may be in contact with the second counter electrode.

According to some embodiments, the display apparatus may further include a remaining counter electrode on the separator.

According to some embodiments, the first counter electrode, the second counter electrode, and the remaining counter electrode may include the same material.

According to some embodiments, the display apparatus may further include a remaining intermediate layer interposed between the separator and the remaining counter electrode.

According to some embodiments, the first intermediate layer, the second intermediate layer, and the remaining intermediate layer may include the same material.

According to some embodiments, the connection electrode may include a material different from the first pixel electrode and the second pixel electrode.

According to some embodiments, the connection electrode may include a material having resistance lower than a material included in the first pixel electrode and the second pixel electrode.

According to some embodiments, when viewed from the direction perpendicular to the substrate (e.g., in the plan view), the separator surrounds the first opening and the second opening, display apparatus.

According to some embodiments, when viewed from the direction perpendicular to the substrate (e.g., in the plan view), the connection electrode may surround the first opening and the second opening.

According to some embodiments, the side surface of the separator may include a reversely tapered inclined surface.

According to some embodiments, the display apparatus may further include a remaining counter electrode on the separator, and the remaining counter electrode may not cover the side surface of the separator.

According to some embodiments, the remaining counter electrode may be spaced apart from the first counter electrode and the second counter electrode.

According to some embodiments, the remaining counter electrode may not be electrically connected to the first counter electrode and the second counter electrode.

According to some embodiments, the display apparatus may further include a remaining intermediate layer interposed between the separator and the remaining counter electrode, and the remaining intermediate layer may not cover the side surface of the separator.

According to some embodiments, the remaining intermediate layer may be spaced apart from the first intermediate layer and the second intermediate layer.

According to some embodiments, the remaining intermediate layer may not be electrically connected to the first intermediate layer and the second intermediate layer.

### BRIEF DESCRIPTION OF THE DRAWINGS

The above and other aspects, features, and characteristics of certain embodiments of the disclosure will be more apparent from the following description taken in conjunction with the accompanying drawings, in which:

FIG. 1 is a schematic plan view of a part of a display apparatus according to some embodiments;

FIG. 2 is an equivalent circuit diagram of one pixel of the display apparatus of FIG. 1;

FIG. 3 is a schematic magnified plan view of a region A of the display apparatus of FIG. 1;

FIG. 4 is a schematic cross-sectional view of the display apparatus of FIG. 3 taken along the line I-I′ of FIG. 3;

FIG. 5A is a schematic magnified cross-sectional view of a region B of the display apparatus of FIG. 4;

FIG. 5B is a schematic magnified cross-sectional view of a region C of the display apparatus of FIG. 4;

FIG. 5C is a schematic magnified cross-sectional view of a region D of the display apparatus of FIG. 4;

FIG. 5D is a schematic magnified cross-sectional view of a region E of the display apparatus of FIG. 4; and

FIG. 6 is a schematic magnified cross-sectional view of a region F of the display apparatus of FIG. 4.

### DETAILED DESCRIPTION

Reference will now be made in more detail to aspects of some embodiments, which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of some embodiments of the present description.

Various modifications may be applied to the present embodiments, and particular embodiments will be illustrated in the drawings and described in the detailed description section. The characteristics of embodiments according to the present disclosure, and a method to achieve the same, will be clearer referring to the detailed descriptions below with the drawings. However, the present embodiments may be implemented in various forms, not by being limited to the embodiments presented below.

Hereinafter, aspects of some embodiments will be described in more detail with reference to the accompanying drawings, and in the description with reference to the drawings, the same or corresponding constituents are indicated by the same reference numerals and redundant descriptions thereof are omitted.

In the following embodiments, it will be understood that when a layer, region, or component is referred to as being “formed on” another layer, region, or component, it can be directly or indirectly formed on the other layer, region, or component. That is, for example, intervening layers, regions, or components may be present. Sizes of components in the drawings may be exaggerated for convenience of explanation. For example, because sizes and thicknesses of components in the drawings are arbitrarily illustrated for convenience of explanation, the following embodiments are not limited thereto.

In the following embodiments, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

In the following embodiments, it will be understood that although the terms “first,” “second,” etc. may be used herein to describe various components, these components should not be limited by these terms. These terms are only used to distinguish one component from another.

In the following embodiments, the expression of singularity in the specification includes the expression of plurality unless clearly specified otherwise in context.

In the following embodiments, it will be further understood that the terms “comprises” and/or “comprising” used herein specify the presence of stated features or components, but do not preclude the presence or addition of one or more other features or components.

In the specification, the expression such as “A and/or B” may include A, B, or A and B. Furthermore, the expression such as “at least one of A and B” may include A, B, or A and B.

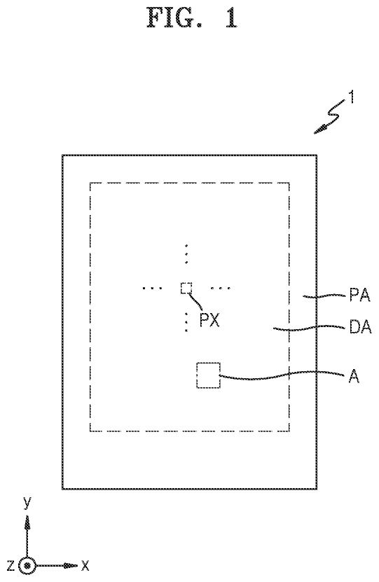

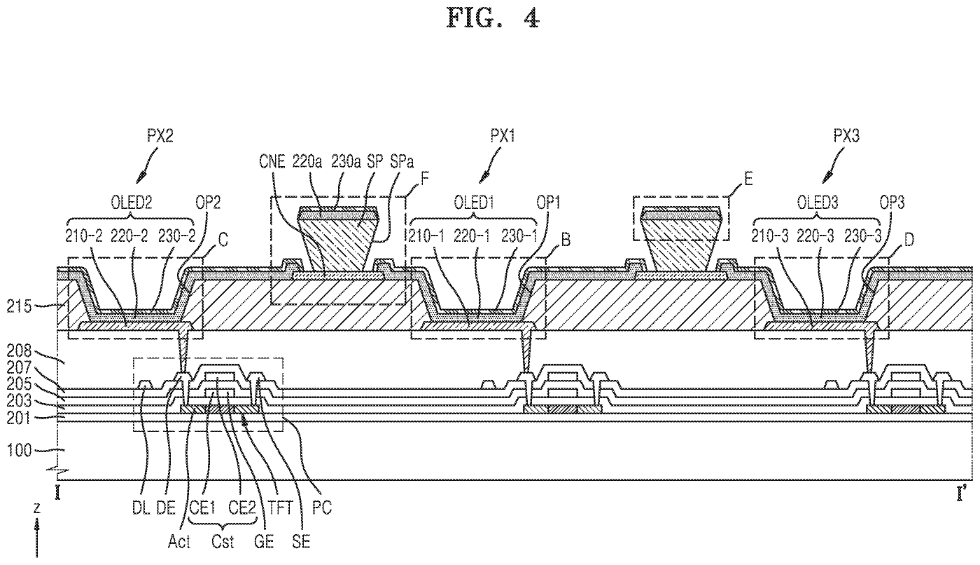

FIG. 1 is a schematic plan view of a part of a display apparatus 1 according to some embodiments. As illustrated in FIG. 1, the display apparatus 1 may include a display area DA in which a plurality of pixels PX are arranged and a peripheral area PA located outside the display area DA. For example, the peripheral area PA may entirely surround the display area DA. This may be understood such that a substrate 100 (see FIG. 4) of the display apparatus 1 includes the display area DA and the peripheral area PA.

Each of the pixels PX of the display apparatus 1 is an area where light of a certain color is emitted, and the display apparatus 1 may provide an image by using light emitted from the pixels PX. For example, each of the pixels PX may emit red light, green light, or blue light.

The display area DA may have, as illustrated in FIG. 1, a polygonal shape including a rectangle. For example, the display area DA may have a rectangular shape in which the horizontal length is longer than the vertical length, a rectangular shape in which the horizontal length is shorter than the vertical length, or a square shape. Alternatively, the display area DA may have various shapes such as an oval or a circle.

The peripheral area PA may be a non-display area where the pixels PX are not arranged. A driver and the like for supplying electrical signals or power to the pixels PX may be arranged in the peripheral area PA. Pads to which various electronic elements, printed circuit boards, or the like ma be electrically connected may be arranged in the peripheral area PA. The pads are spaced apart from each other in the peripheral area PA, and may be electrically connected to printed circuit boards or integrated circuit devices.

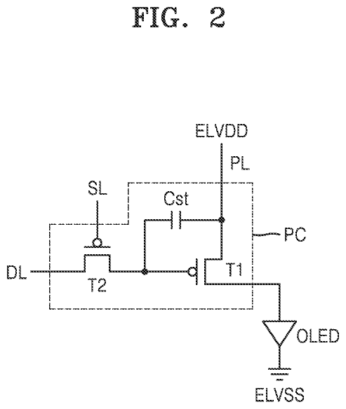

FIG. 2 is an equivalent circuit diagram of one pixel PX of the display apparatus 1 of FIG. 1. As illustrated in FIG. 2, one pixel PX may include a pixel circuit PC and an organic light-emitting diode OLED electrically connected to the pixel circuit PC.

The pixel circuit PC may include a first transistor T1, a second transistor T2, and a storage capacitor Cst. The second transistor T2, as a switching transistor, is connected to a scan line SL and a data line DL, and turned on in response to a switching signal input from the scan line SL to transmit a data signal input from the data line DL to the first transistor T1. One end of the storage capacitor Cst is electrically connected to the second transistor T2 and the other end thereof is electrically connected to a driving voltage line PL, and the storage capacitor Cst may store a voltage corresponding to a difference between a voltage received from the second transistor T2 and a driving power voltage ELVDD supplied through the driving voltage line PL.

The first transistor T1, as a driving transistor, is connected to the driving voltage line PL and the storage capacitor Cst, and may control the magnitude of a driving current flowing from the driving voltage line PL to the organic light-emitting diode OLED, corresponding to a voltage value stored in the storage capacitor Cst. The organic light-emitting diode OLED may emit light having a certain luminance, in response to the driving current. A counter electrode of the organic light-emitting diode OLED may receive an electrode power voltage ELVSS.

Although FIG. 2 illustrates that the pixel circuit PC includes two transistors and one storage capacitor, the disclosure is not limited thereto. For example, the number of transistors or storage capacitors may vary variously depending on the design of the pixel circuit PC.

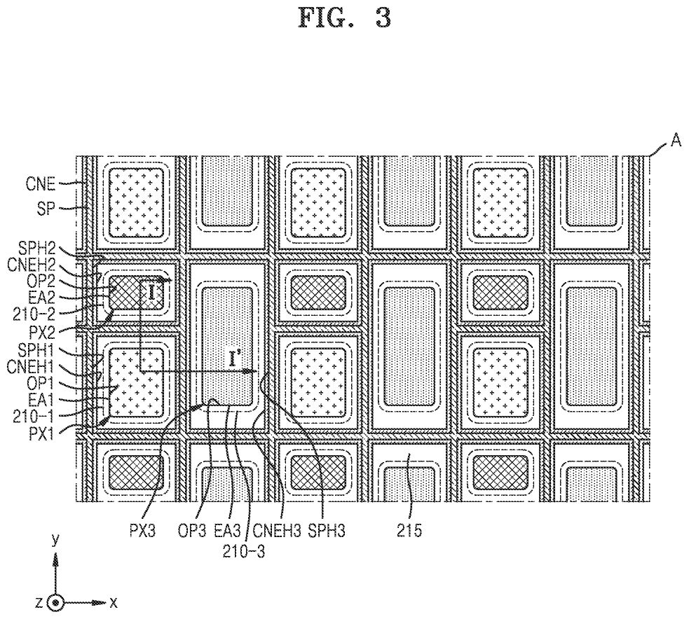

FIG. 3 is a schematic magnified plan view of a region A of the display apparatus 1 of FIG. 1. FIG. 3 is a plan view on a pixel defining layer 215, for convenience of explanation. However, for convenience of explanation, a connection electrode CNE and a separator SP arranged on the pixel defining layer 215 are illustrated together.

As illustrated in FIG. 3, the pixels PX may be arranged in the display area DA of the substrate 100. Each of the pixels PX signifies a sub-pixel, and may include a display element such as the organic light-emitting diode OLED. Each of the pixels PX may emit, for example, green light, red light, or blue light. For example, each of the pixels PX may be a first pixel PX1 for emitting green light, a second pixel PX2 for emitting red light, or a third pixel PX3 for emitting blue light. The green light may be light in a wavelength band of 495 nm to 580 nm, and the red light may be light in a wavelength band of 580 nm to 780 nm, and the blue light may be light in a wavelength band of 400 nm to 495 nm.

A first pixel electrode 210-1 of the first pixel PX1, a second pixel electrode 210-2 of the second pixel PX2, and a third pixel electrode 210-3 of the third pixel PX3 may be arranged in the display area DA. For example, the first pixel electrode 210-1, the second pixel electrode 210-2, and the third pixel electrode 210-3 may be spaced apart from one another on a plane. The first pixel electrode 210-1, the second pixel electrode 210-2, and the third pixel electrode 210-3 may have different sizes, as illustrated in FIG. 3. According to some embodiments, the first pixel electrode 210-1, the second pixel electrode 210-2, and the third pixel electrode 210-3 may have the same size.

The pixel defining layer 215 is located above the first pixel electrode 210-1, the second pixel electrode 210-2, and the third pixel electrode 210-3, and may include a first opening OP1, a second opening OP2, and a third opening OP3. The first opening OP1 may expose a central portion of the first pixel electrode 210-1, the second opening OP2 may expose a central portion of the second pixel electrode 210-2, and the third opening OP3 may expose a central portion of the third pixel electrode 210-3. The first opening OP1, the second opening OP2, and the third opening OP3 may have different sizes, as illustrated in FIG. 3. According to some embodiments, the first opening OP1, the second opening OP2, and the third opening OP3 may have the same size.

According to some embodiments, emission layers for emitting light may be located in each of the first opening OP1, the second opening OP2, and the third opening OP3 of the pixel defining layer 215. Counter electrodes may be arranged on the emission layers. A stack structure of the pixel electrode, the emission layer, and the counter electrode may form one organic light-emitting diode OLED. One opening of the pixel defining layer 215 may correspond to one organic light-emitting diode OLED, and define one emission area.

For example, a emission layer for emitting green light is arranged in the first opening OP1, and the first pixel PX1 may include a first emission area EA1 defined by the first opening OP1. Similarly, a emission layer for emitting red light is arranged in the second opening OP2, and the second pixel PX2 may include a second emission area EA2 defined by the second opening OP2. Similarly, an emission layer for emitting blue light is arranged in the third opening OP3, and the third pixel PX3 may include a third emission area EA3 defined by the third opening OP3. However, the disclosure is not limited thereto. For example, a emission layer for emitting blue light or green light may be arranged in the first opening OP1, the second opening OP2, and the third opening OP3. In this case, the display apparatus 1 may include a light-emitting panel and a color panel stacked in a thickness direction, for example, a z-axis direction, and blue light or green light emitted from the emission layer of the light-emitting panel may be converted into green light, red light, and blue light while passing through the color panel, or may transmit through the color panel.

The first opening OP1 and the second opening OP2 may be located adjacent to each other in a second direction, for example, a y-axis direction, crossing a first direction, for example, an x-axis direction, and the first opening OP1 and the third opening OP3 may be located adjacent to each other in the first direction, for example, the x-axis direction. As illustrated in FIG. 3, as each of the size of the first opening OP1 and the size of the second opening OP2 is less than the size of the third opening OP3, and the second opening OP2 is located adjacent to the first opening OP1 in the second direction, for example, the y-axis direction, the third opening OP3 and the second opening OP2 may be located adjacent to each other in the first direction, for example, the x-axis direction.

The separator SP may be located on the pixel defining layer 215. For example, when viewed from a direction perpendicular to the substrate 100 (e.g., in a plan view), for example, the z-axis direction, the separator SP may be located on the pixel defining layer 215 to surround the openings of the pixel defining layer 215, for example, the first opening OP1, the second opening OP2, and the third opening OP3. In other words, the separator SP may have a mesh structure. For example, the first opening OP1 may be located in a first separator hole SPH1 defined by the separator SP surrounding the first opening OP1 on a plane. Similarly, the second opening OP2 may be located in a second separator hole SPH2 defined by the separator SP on a plane, and the third opening OP3 may be located in a third separator hole SPH3 defined by the separator SP on a plane. Accordingly, the separator SP may be located between neighboring openings (or pixels).

Although FIG. 3 illustrates that each of the first separator hole SPH1, the second separator hole SPH2, and the third separator hole SPH3 has a rectangular shape, the disclosure is not limited thereto. For example, the first separator hole SPH1, the second separator hole SPH2, and/or the third separator hole SPH3 may have a polygonal shape including a rectangle. In other words, each of the first separator hole SPH1, the second separator hole SPH2, and/or the third separator hole SPH3 may have a rectangular shape in which the horizontal length is longer than the vertical length, a rectangular shape in which the horizontal length is shorter than the vertical length, or a square shape. Alternatively, the first separator hole SPH1, the second separator hole SPH2, and/or the third separator hole SPH3 may have various shapes such as an oval or a circle.

Although FIG. 3 illustrates that the separator SP entirely surrounds each of the openings of the pixel defining layer 215, for example, the first opening OP1, the second opening OP2, and the third opening OP3, the disclosure is not limited thereto. For example, the separator SP may partially surround each of the openings of the pixel defining layer 215, for example, the first opening OP1, the second opening OP2, and the third opening OP3.

The connection electrode CNE may be located below the separator SP. In other words, the connection electrode CNE may be interposed between the separator SP and the pixel defining layer 215. For example, when viewed from the direction perpendicular to the substrate 100 (e.g., in a plan view), for example, the z-axis direction, the connection electrode CNE may be located on the pixel defining layer 215 to overlap the separator SP.

The connection electrode CNE may have the same shape, for example, a mesh structure, as the pixel defining layer 215. Accordingly, when viewed from the direction perpendicular to the substrate 100 (e.g., in a plan view), for example, the z-axis direction, the connection electrode CNE may surround the openings of the pixel defining layer 215, for example, the first opening OP1, the second opening OP2, and the third opening OP3. For example, the first opening OP1 may be located in a first connection electrode hole CNEH1 defined by the connection electrode CNE surrounding the first opening OP1 on a plane. Similarly, the second opening OP2 may be located in a second connection electrode hole CNEH2 defined by the connection electrode CNE on a plane, and the third opening OP3 may be located in the third separator hole SPH3 defined by the connection electrode CNE on a plane. Accordingly, the connection electrode CNE may be located between the neighboring openings (or pixels). The first connection electrode hole CNEH1 may be smaller than or equal to the first separator hole SPH1. Similarly, the second connection electrode hole CNEH2 may be smaller than or equal to the second separator hole SPH2, and a third connection electrode hole CNEH3 may be smaller than or equal to the third separator hole SPH3.

Although FIG. 3 illustrates that each of the first connection electrode hole CNEH1, the second connection electrode hole CNEH2, and the third connection electrode hole CNEH3 has a rectangular shape, the disclosure is not limited thereto. For example, the first connection electrode hole CNEH1, the second connection electrode hole CNEH2, and/or the third connection electrode hole CNEH3 may have a polygonal shape including a rectangle. In other words, each of the first connection electrode hole CNEH1, the second connection electrode hole CNEH2, and/or the third connection electrode hole CNEH3 may have a rectangular shape in which the horizontal length is longer than the vertical length, a rectangular shape in which the horizontal length is shorter than the vertical length, or a square shape. Alternatively, the first connection electrode hole CNEH1, the second connection electrode hole CNEH2, and/or the third connection electrode hole CNEH3 may have various shapes such as an oval or a circle.

Although FIG. 3 illustrates that a plurality of pixels PX are arranged in a stripe type, the pixels PX may be arranged in various forms such as an RGBG type (a so-called pentile® structure) and the like.

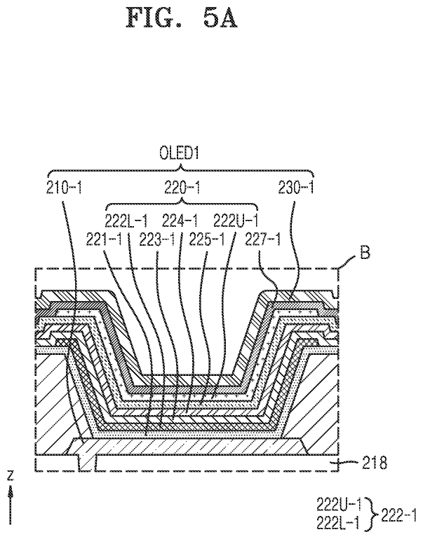

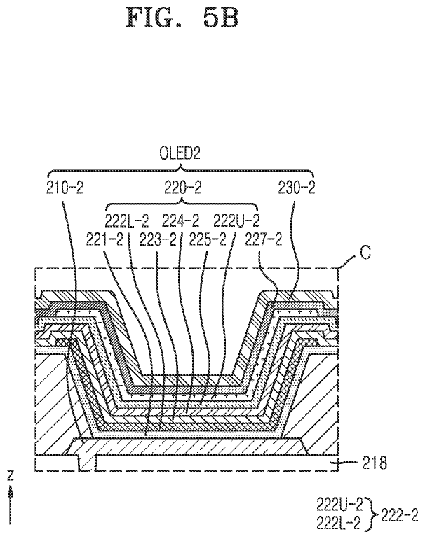

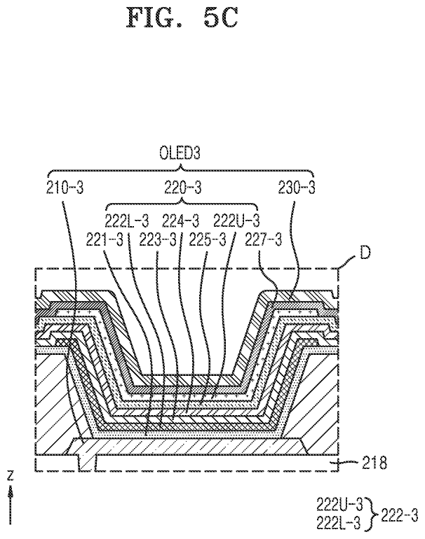

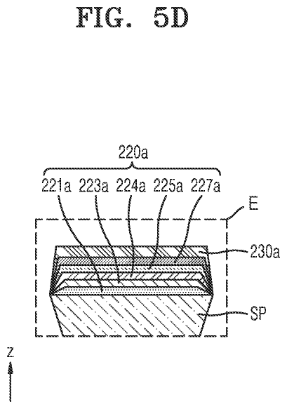

FIG. 4 is a schematic cross-sectional view showing a part of the display apparatus 1 of FIG. 3. For example, FIG. 4 is a schematic cross-sectional view of the display apparatus 1 taken along line I-I′ of FIG. 3. FIG. 5A is a schematic magnified cross-sectional view of a region B of the display apparatus 1 of FIG. 4. FIG. 5B is a schematic magnified cross-sectional view of a region C of the display apparatus 1 of FIG. 4. FIG. 5C is a schematic magnified cross-sectional view of a region D of the display apparatus 1 of FIG. 4.

As illustrated in FIG. 4, the display apparatus 1 according to some embodiments may include the substrate 100. The substrate 100 may include various materials having flexibility or bendability. For example, the substrate 100 may include glass, metal, or polymer resin. Furthermore, the substrate 100 may include polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 may vary variously, for example, in a multilayer structure including two layers including polymer resin described above and a barrier layer interposed between the layers and including an inorganic material, such as a silicon oxide, a silicon nitride, a silicon oxynitride, and the like.

The pixels PX including a plurality of display elements and the pixel circuit PC may be arranged on the substrate 100. In FIG. 4, each of the pixels PX includes the organic light-emitting diode OLED as a display element. For example, the organic light-emitting diode OLED may be a first organic light-emitting diode OLED1, a second organic light-emitting diode OLED2, or a third organic light-emitting diode OLED3. In other words, the first pixel PX1 may include the first organic light-emitting diode OLED1, the second pixel PX2 may include the second organic light-emitting diode OLED2, and the third pixel PX3 may include the third organic light-emitting diode OLED3.

The pixel circuit PC may be located on the substrate 100. As the structure of the pixel circuit PC of each of the pixels PX is the same, one pixel circuit PC is mainly described. The pixel circuit PC may include a plurality of thin film transistors TFT and the storage capacitor Cst. For convenience of illustration, FIG. 4 illustrates one thin film transistor TFT, and the thin film transistor TFT may correspond to the first transistor T1 of FIG. 2 described above, as a driving transistor.

A buffer layer 201 including an inorganic material, such as a silicon oxide, a silicon nitride, a silicon oxynitride, and/or the like may be interposed between the thin film transistor TFT and the substrate 100. The buffer layer 201 may increase smoothness of an upper surface of the substrate 100, or prevent or reduce infiltration of impurities from the substrate 100 and the like into a semiconductor layer Act of the thin film transistor TFT.

As illustrated in FIG. 4, the thin film transistor TFT may include the semiconductor layer Act including amorphous silicon, polycrystalline silicon, an organic semiconductor material, or an oxide semiconductor material. The thin film transistor

TFT may include a gate electrode GE, a source electrode SE, and/or a drain electrode DE. The gate electrode GE may include various conductive materials and have various layered structures including, for example, a Mo layer and an Al layer. Alternatively, the gate electrode GE may include a TiNx layer, an Al layer, and/or a Ti layer. The source electrode SE and the drain electrode DE may also include various conductive materials and have various layered structures including, for example, a Ti layer, an Al layer, and/or a Cu layer.

To secure insulation between the semiconductor layer Act and the gate electrode GE, a gate insulating layer 203 including an inorganic material, such as a silicon oxide, a silicon nitride, a silicon oxynitride, and/or like may be interposed between the semiconductor layer Act and the gate electrode GE. Although FIG. 4 illustrates that the gate insulating layer 203 has a shape corresponding to the entire surface of the substrate 100, and has a structure in which contact holes are formed in preset portions, the disclosure is not limited thereto. For example, the gate insulating layer 203 may be patterned in the same shape as the gate electrode GE.

In addition, a first interlayer insulating layer 205 including an inorganic material, such as a silicon oxide, a silicon nitride, a silicon oxynitride, and/or like may be located above the gate electrode GE. The first interlayer insulating layer 205 may have a single layer or multilayer structure including the material described above. As such, an insulating film including an inorganic material may be formed by a chemical vapor deposition (CVD) method or an atomic layer deposition (ALD) method. This also applies to embodiments and modified examples thereof which are described below.

The storage capacitor Cst may include a first electrode CE1 and a second electrode CE2, which overlap each other with the first interlayer insulating layer 205 therebetween. The storage capacitor Cst may overlap the thin film transistor TFT. In this connection, although FIG. 4 illustrates that the gate electrode GE of the thin film transistor TFT is the first electrode CE1 of the storage capacitor Cst, the disclosure is not limited thereto. For example, the storage capacitor Cst may not overlap the thin film transistor TFT. The second electrode CE2 of the storage capacitor Cst may include a conductive material, such as molybdenum (Mo), aluminum (Al), copper (Cu), titanium (Ti), and the like, and may have a multilayer or single layer structure including the above materials.

A second interlayer insulating layer 207 including an inorganic material, such as a silicon oxide, a silicon nitride, a silicon oxynitride, and/or like, may be located above the second electrode CE2 of the storage capacitor Cst. The second interlayer insulating layer 207 may have a single layer or multilayer structure including the material described above.

The source electrode SE and the drain electrode DE may be located on the second interlayer insulating layer 207. The data line DL may be located on the same layer, and may include the same material, as the source electrode SE and the drain electrode DE. The source electrode SE, the drain electrode DE, and the data line DL may include an excellent conductive material. The source electrode SE and the drain electrode DE may each include a conductive material including Mo, Al, Cu, Ti, and the like, and may have a multilayer or single layer structure including the above materials. For example, the source electrode SE, the drain electrode DE, and the data line DL may each have a multilayer structure of Ti/Al/Ti.

The disclosure is not limited thereto. For example, the thin film transistor TFT may include any one of the source electrode SE and the drain electrode DE, or may include none of the source electrode SE and the drain electrode DE. For example, one thin film transistor TFT does not include the drain electrode DE, the other thin film transistor TFT connected to the one thin film transistor TFT does not include the source electrode SE, and the semiconductor layers Act of the two thin film transistors may be connected to each other. Such a connection structure may have the same effect as a structure in which the one thin film transistor TFT further includes the source electrode SE, the other thin film transistor TFT further includes the drain electrode DE, and the source electrode SE of the one thin film transistor TFT is connected to the drain electrode DE of the other thin film transistor TFT.

As illustrated in FIG. 4, a planarization layer 208 may be arranged to cover the thin film transistor TFT and the storage capacitor Cst. The planarization layer 208 may include an organic insulating material. For example, the planarization layer 208 may include photoresist, benzocyclobutene (BCB), polyimide, hexamethyldisiloxane (HMDSO), polymethylmethacrylate (PMMA), polystyrene, polymer derivatives having a phenolic group, acrylic polymers, imide-based polymers, arylether-based polymers, amide-based polymers, fluorine-based polymers, p-xylene-based polymers, vinyl alcohol-based polymers, mixtures thereof, or the like. According to some embodiments, a third interlayer insulating layer may be further located below the planarization layer 208. The third interlayer insulating layer may include an inorganic insulating material, such as a silicon oxide, a silicon nitride, or a silicon oxynitride.

The first organic light-emitting diode OLED1, the second organic light-emitting diode OLED2, and the third organic light-emitting diode OLED3 may be spaced apart from one another on the planarization layer 208. For example, the first organic light-emitting diode OLED1 and the second organic light-emitting diode OLED2 that are adjacent to each other in the second direction, for example, the y-axis direction, crossing the first direction, for example, the x-axis direction, may be located on the planarization layer 208, and the third organic light-emitting diode OLED3 may be located on the planarization layer 208 to be adjacent to the first organic light-emitting diode OLED1 in the first direction, for example, the x-axis direction. The first organic light-emitting diode OLED1, the second organic light-emitting diode OLED2, and the third organic light-emitting diode OLED3 may respectively emit light of different colors. For example, the first organic light-emitting diode OLED1 may emit green light, the second organic light-emitting diode OLED2 may emit red light, and the third organic light-emitting diode OLED3 may emit blue light.

The first organic light-emitting diode OLED1 may include the first pixel electrode 210-1, a first intermediate layer 220-1, and a first counter electrode 230-1. The second organic light-emitting diode OLED2 may include the second pixel electrode 210-2, a second intermediate layer 220-2, and a second counter electrode 230-2. The third organic light-emitting diode OLED3 may include the third pixel electrode 210-3, a third intermediate layer 220-3, and a third counter electrode 230-3.

The first pixel electrode 210-1 and the second pixel electrode 210-2 may be spaced apart from each other on the planarization layer 208. For example, the second pixel electrode 210-2 may be arranged adjacent to the first pixel electrode 210-1 in the second direction, for example, the y-axis direction, on the planarization layer 208. The third pixel electrode 210-3 may be arranged on the planarization layer 208 apart from the first pixel electrode 210-1. For example, the third pixel electrode 210-3 may be arranged adjacent to the first pixel electrode 210-1 in the first direction, for example, the x-axis direction, on the planarization layer 208.

The first pixel electrode 210-1, the second pixel electrode 210-2, and the third pixel electrode 210-3 may each include a light-transmissive conductive layer including a conductive oxide, such as ITO, In₂O₃, IZO, or the like, which is light-transmissive, and a reflective layer including a metal, such as Al, Ag, or the like. For example, the first pixel electrode 210-1, the second pixel electrode 210-2, and the third pixel electrode 210-3 may each have a three-layer structure of ITO/Ag/ITO.

The first pixel electrode 210-1, the second pixel electrode 210-2, and the third pixel electrode 210-3 may each be in contact with any one of the source electrode SE and the drain electrode DE, as illustrated in FIG. 4, and may be electrically connected to the thin film transistor TFT. For example, the first pixel electrode 210-1, the second pixel electrode 210-2, and the third pixel electrode 210-3 may each be in contact with any one of the source electrode SE and the drain electrode DE via a contact hole formed in the planarization layer 208.

The pixel defining layer 215 may be located on the planarization layer 208. The pixel defining layer 215 having an opening corresponding to each of the pixels PX, that is, an opening exposing the central portion of at least pixel electrode may define each of the pixels PX. For example, the pixel defining layer 215 may have the first opening OP1, the second opening OP2, and the third opening OP3. The first opening OP1 may expose the central portion of the first pixel electrode 210-1, the second opening OP2 may expose the central portion of the second pixel electrode 210-2, and the third opening OP3 may expose the central portion of the third pixel electrode 210-3. Furthermore, as in the case illustrated in FIG. 4, the pixel defining layer 215 may increase a distance between an edge of the first pixel electrode 210-1 and the first counter electrode 230-1 above the first pixel electrode 210-1. Similarly, the pixel defining layer 215 may increase a distance between an edge of the second pixel electrode 210-2 and the second counter electrode 230-2, and increase a distance between an edge of the third pixel electrode 210-3 and the third counter electrode 230-3. Accordingly, the generation of arc and the like in the edge of the first pixel electrode 210-1, the edge of the second pixel electrode 210-2, or the edge of the third pixel electrode 210-3 may be prevented. The pixel defining layer 215 described above may include an organic material, such as polyimide, HMDSO or the like.

The first intermediate layer 220-1 may be located on the first pixel electrode 210-1. The second intermediate layer 220-2 may be located on the second pixel electrode 210-2, and the third intermediate layer 220-3 may be located on the third pixel electrode 210-3. The first intermediate layer 220-1, the second intermediate layer 220-2, and the third intermediate layer 220-3 may be spaced apart from one another on a plane. In other words, the second intermediate layer 220-2 may be spaced apart from the first intermediate layer 220-1 on a plane, and the third intermediate layer 220-3 may be spaced apart from the first intermediate layer 220-1 and the second intermediate layer 220-2 on a plane.

The first intermediate layer 220-1, the second intermediate layer 220-2, and the third intermediate layer 220-3 may each include a low molecular weight or polymer material. When each of the first intermediate layer 220-1, the second intermediate layer 220-2, and the third intermediate layer 220-3 includes a low molecular weight material, the first intermediate layer 220-1, the second intermediate layer 220-2, and the third intermediate layer 220-3 may each have a stack structure of a hole injection layer (HIL), a hole transport layer (HTL), an emission layer (EML), an electron transport layer (ETL), an electron injection layer (EIL), and the like, in a single or composite structure, and may be formed by a vacuum deposition method.

When each of the first intermediate layer 220-1, the second intermediate layer 220-2, and the third intermediate layer 220-3 includes a polymer material, the first intermediate layer 220-1, the second intermediate layer 220-2, and the third intermediate layer 220-3 may each have a structure including the HTL and the EML. In this case, the HTL may include poly-(3,4-ethylenedioxythiophene) (PEDOT), and the EML may include a polymer material based on polyphenylene vinylene (PPV), polyfluorene, and the like. The first intermediate layer 220-1, the second intermediate layer 220-2, and the third intermediate layer 220-3 may each be formed by a screen printing method, an inkjet printing method, a laser induced thermal imaging (LITI) method, and the like.

As illustrated in FIG. 5A, the first intermediate layer 220-1 of the first organic light-emitting diode OLED1 may include a first-1 common layer 221-1, a first emission layer 222-1, and a second-1 common layer 227-1. The first emission layer 222-1 may include a polymer or low molecular weight organic material that emits light of a certain color. In other words, the first emission layer 222-1 may emit light of a certain wavelength band. For example, the first emission layer 222-1 may emit green light. The green light may be light in a wavelength band of 495 nm to 580 nm.

As illustrated in FIG. 5A, the first organic light-emitting diode OLED1 may have a tandem structure. For example, the first organic light-emitting diode OLED1 may include a first lower emission layer 222L-1 and a first upper emission layer 222U-1, and the first upper emission layer 222U-1 may be located on the first lower emission layer 222L-1 to overlap the first lower emission layer 222L-1. In other words, the first emission layer 222-1 may include the first lower emission layer 222L-1 and the first upper emission layer 222U-1.

The first-1 common layer 221-1 may be interposed between the first pixel electrode 210-1 and the first lower emission layer 222L-1. The first-1 common layer 221-1 may have a single layer or multilayer structure. For example, when the first-1 common layer 221-1 includes a polymer material, the first-1 common layer 221-1, as the HTL that is a single layer structure, may include PEDOT, polyaniline (PANI), N, N′-diphenyl-N,N′-bis(3-methylphenyl)-1,1′-bi-phenyl-4,4′-diamine (TPD), or N,N′-di(naphthalen-1-yl)-N,N′-diphenyl-benzidine (NPB). When the first-1 common layer 221-1 includes a low molecular weight material, the first-1 common layer 221-1 may include the HIL and the HTL.

The second-1 common layer 227-1 may be located on the first upper emission layer 222U-1. The second-1 common layer 227-1 may not always be provided. For example, when each of the first-1 common layer 221-1 and the first emission layer 222-1 includes a polymer material, the second-1 common layer 227-1 may be formed. The second-1 common layer 227-1 may have a single layer or multilayer structure. The second-1 common layer 227-1 may include the ETL and/or the EIL. The first counter electrode 230-1 may be located on the second-1 common layer 227-1.

The first intermediate layer 220-1 may further include a first charge generation layer 224-1. The first charge generation layer 224-1 may be located between the first lower emission layer 222L-1 and the first upper emission layer 222U-1. The first charge generation layer 224-1 may supply electric charges to a first stack including the first lower emission layer 222L-1 and a second stack including the first upper emission layer 222U-1.

The first intermediate layer 220-1 may further include a third-1 common layer 223-1 and a fourth-1 common layer 225-1. The third-1 common layer 223-1 may be located between the first lower emission layer 222L-1 and the first charge generation layer 224-1. The fourth-1 common layer 225-1 may be located between the first charge generation layer 224-1 and the first upper emission layer 222U-1. The third-1 common layer 223-1 may include the ETL, and the fourth-1 common layer 225-1 may include the HTL.

For example, the first intermediate layer 220-1 may include the first-1 common layer 221-1, the first lower emission layer 222L-1, the third-1 common layer 223-1, the first charge generation layer 224-1, the fourth-1 common layer 225-1, the first upper emission layer 222U-1, and the second-1 common layer 227-1.

As illustrated in FIG. 5B, the second intermediate layer 220-2 of the second organic light-emitting diode OLED2 may include a first-2 common layer 221-2, a second emission layer 222-2, and a second-2 common layer 227-2. The second emission layer 222-2 of the second organic light-emitting diode OLED2 may emit light of a wavelength band different from the first emission layer 222-1 of the first organic light-emitting diode OLED1. For example, the second emission layer 222-2 may emit red light. The red light may be light in a wavelength band of 580 nm to 780 nm.

As illustrated in FIG. 5B, the second organic light-emitting diode OLED2 may have a tandem structure. For example, the second organic light-emitting diode OLED2 may include a second lower emission layer 222L-2 and a second upper emission layer 222U-2, and the second upper emission layer 222U-2 may be located on the second lower emission layer 222L-2 to overlap the second lower emission layer 222L-2. In other words, the second emission layer 222-2 may include the second lower emission layer 222L-2 and the second upper emission layer 222U-2.

The first-2 common layer 221-2 may be interposed between second pixel electrode 210-2 and the second lower emission layer 222L-2. The second-2 common layer 227-2 may be located on the second upper emission layer 222U-2. The second intermediate layer 220-2 may further include a second charge generation layer 224-2, and the second charge generation layer 224-2 may be located between the second lower emission layer 222L-2 and the second upper emission layer 222U-2. The second intermediate layer 220-2 may further include a third-2 common layer 223-2 and a fourth-2 common layer 225-2. For example, the second intermediate layer 220-2 may include the first-2 common layer 221-2, the second lower emission layer 222L-2, the third-2 common layer 223-2, the second charge generation layer 224-2, the fourth-2 common layer 225-2, the second upper emission layer 222U-2, and the second-2 common layer 227-2.

As the descriptions with respect to the first-1 common layer 221-1, the third-1 common layer 223-1, the first charge generation layer 224-1, the fourth-1 common layer 225-1, and the second-1 common layer 227-1 may be respectively applied to the first-2 common layer 221-2, the third-2 common layer 223-2, the second charge generation layer 224-2, the fourth-2 common layer 225-2, and the second-2 common layer 227-2, redundant descriptions in this connection are omitted.

As illustrated in FIG. 5C, the third intermediate layer 220-3 of the third organic light-emitting diode OLED3 may include a first-3 common layer 221-3, a third emission layer 222-3, and a second-3 common layer 227-3. The third emission layer 222-3 of the third organic light-emitting diode OLED3 may emit light of a wavelength band different from the first emission layer 222-1 of the first organic light-emitting diode OLED1 and the second emission layer 222-2 of the second organic light-emitting diode OLED2. For example, the third emission layer 222-3 may emit blue light. The blue light may be light in a wavelength band of 400 nm to 495 nm.

As illustrated in FIG. 5C, the third organic light-emitting diode OLED3 may have a tandem structure. For example, the third organic light-emitting diode OLED3 may include a third lower emission layer 222L-3 and a third upper emission layer 222U-3, and the third upper emission layer 222U-3 may be located on the third lower emission layer 222L-3 to overlap the third lower emission layer 222L-3. In other words, the third emission layer 222-3 may include the third lower emission layer 222L-3 and the third upper emission layer 222U-3.

The first-3 common layer 221-3 may be interposed between the third pixel electrode 210-3 and the third lower emission layer 222L-3. The second-3 common layer 227-3 may be located on the third upper emission layer 222U-3. The third intermediate layer 220-3 may further include a third charge generation layer 224-3, and the third charge generation layer 224-3 may be located between the third lower emission layer 222L-3 and the third upper emission layer 222U-3. The third intermediate layer 220-3 may further include a third-3 common layer 223-3 and a fourth-3 common layer 225-3. For example, the third intermediate layer 220-3 may include the first-3 common layer 221-3, the third lower emission layer 222L-3, the third-3 common layer 223-3, the third charge generation layer 224-3, the fourth-3 common layer 225-3, the third upper emission layer 222U-3, and the second-3 common layer 227-3.

As the descriptions with respect to the first-1 common layer 221-1, the third-1 common layer 223-1, the first charge generation layer 224-1, the fourth-1 common layer 225-1 and the second-1 common layer 227-1 may be respectively applied to the first-3 common layer 221-3, the third-3 common layer 223-3, the third charge generation layer 224-3, the fourth-3 common layer 225-3, and the second-3 common layer 227-3, redundant descriptions in this connection are omitted.

The first-1 common layer 221-1, the first-2 common layer 221-2, and the first-3 common layer 221-3 may be simultaneously formed of the same material in the same process. For example, when the material for forming the first-1 common layer 221-1, the first-2 common layer 221-2, and the first-3 common layer 221-3 may be deposited on the entire surface of the substrate 100. The third-1 common layer 223-1, the third-2 common layer 223-2, and the third-3 common layer 223-3 may be simultaneously formed of the same material in the same process, and the first charge generation layer 224-1, the second charge generation layer 224-2, and the third charge generation layer 224-3 may be simultaneously formed of the same material in the same process. For example, when the material for forming the third-1 common layer 223-1, the third-2 common layer 223-2, and the third-3 common layer 223-3 may be deposited on the entire surface of the substrate 100, and the material for forming the first charge generation layer 224-1, the second charge generation layer 224-2, and the third charge generation layer 224-3 may be deposited on the entire surface of the substrate 100.

The fourth-1 common layer 225-1, the fourth-2 common layer 225-2, and the fourth-3 common layer 225-3 may be simultaneously formed of the same material in the same process, and the second-1 common layer 227-1, the second-2 common layer 227-2, and the second-3 common layer 227-3 may be simultaneously formed of the same material in the same process. For example, when the material for forming the fourth-1 common layer 225-1, the fourth-2 common layer 225-2, and the fourth-3 common layer 225-3 may be deposited on the entire surface of the substrate 100, and the material for forming the second-1 common layer 227-1, the second-2 common layer 227-2, and the second-3 common layer 227-3 may be deposited on the entire surface of the substrate 100.

The first counter electrode 230-1 may be located on the first intermediate layer 220-1. The second counter electrode 230-2 may be located on the second intermediate layer 220-2, and the third counter electrode 230-3 may be located on the third intermediate layer 220-3. In other words, the first intermediate layer 220-1 may be interposed between the first pixel electrode 210-1 and the first counter electrode 230-1, the second intermediate layer 220-2 may be interposed between the second pixel electrode 210-2 and the second counter electrode 230-2, and the third intermediate layer 220-3 may be interposed between the third pixel electrode 210-3 and the third counter electrode 230-3. The first counter electrode 230-1, the second counter electrode 230-2, and the third counter electrode 230-3 may be spaced apart from one another on a plane. In other words, the second counter electrode 230-2 may be spaced apart from the first counter electrode 230-1 on a plane, and the third counter electrode 230-3 may be spaced apart from the first counter electrode 230-1 and the second counter electrode 230-2 on a plane.

The first counter electrode 230-1, the second counter electrode 230-2, and the third counter electrode 230-3 may each include a light-transmissive conductive layer including ITO, In₂O₃, or IZO, and also include a semi-transmissive film including a metal, such as Al, Ag, or the like. For example, the first counter electrode 230-1, the second counter electrode 230-2, and the third counter electrode 230-3 may each include a semi-transmissive film including Mg or Ag. According to some embodiments, a capping layer may be located on the first counter electrode 230-1, the second counter electrode 230-2, and the third counter electrode 230-3. For example, the capping layer may include a material selected from among an organic material, an inorganic material, and mixtures thereof, and may be provided in a single layer or multilayer. A LiF layer may be located on the capping layer according to some embodiments. The first counter electrode 230-1, the second counter electrode 230-2, and the third counter electrode 230-3 may be simultaneously formed of the same material in the same process. For example, when the material for forming the first counter electrode 230-1, the second counter electrode 230-2, and the third counter electrode 230-3 may be deposited on the entire surface of the substrate 100.

The separator SP may be located above the pixel defining layer 215. For example, when viewed from the direction perpendicular to the substrate 100 (e.g., in a plan view), the separator SP may be arranged between the first opening OP1 and the second opening OP2. As described above with reference to FIG. 3, when viewed from the direction perpendicular to the substrate 100 (e.g., in a plan view), the separator SP may surround the first opening OP1. Accordingly, when viewed from the direction perpendicular to the substrate 100 (e.g., in a plan view), the separator SP may be arranged between the first opening OP1 and the third opening OP3.

A remaining intermediate layer 220a and a remaining counter electrode 230a may be located on the separator SP. FIG. 5D is a schematic magnified cross-sectional view of a region E of the display apparatus 1 of FIG. 4. As illustrated in FIG. 5D, the remaining intermediate layer 220a may include a first remaining common layer 221a, a third remaining common layer 223a, a remaining charge generation layer 224a, a fourth remaining common layer 225A, and a second remaining common layer 227a.

The first remaining common layer 221a, the first-1 common layer 221-1, the first-2 common layer 221-2, and the first-3 common layer 221-3 may be simultaneously formed of the same material in the same process. For example, when the material for forming the first-1 common layer 221-1, the first-2 common layer 221-2, and the first-3 common layer 221-3 are deposed on the entire surface of the substrate 100, a layer formed on the separator SP may be the first remaining common layer 221a. The third remaining common layer 223a, the third-1 common layer 223-1, the third-2 common layer 223-2, and the third-3 common layer 223-3 may be simultaneously formed of the same material in the same process. For example, when the material for forming the third-1 common layer 223-1, the third-2 common layer 223-2, and the third-3 common layer 223-3 is deposited on the entire surface of the substrate 100, a layer formed above the separator SP may be the third remaining common layer 223a. For example, the third remaining common layer 223a may be formed on the first remaining common layer 221a.

The remaining charge generation layer 224a, the first charge generation layer 224-1, the second charge generation layer 224-2, and the third charge generation layer 224-3 may be simultaneously formed of the same material in the same process. For example, when the material for forming the first charge generation layer 224-1, the second charge generation layer 224-2, and the third charge generation layer 224-3 is deposited on the entire surface of the substrate 100, a layer formed above the separator SP may be the remaining charge generation layer 224a. For example, the remaining charge generation layer 224a may be formed on the third remaining common layer 223a. The fourth remaining common layer 225A, the fourth-1 common layer 225-1, the fourth-2 common layer 225-2, and the fourth-3 common layer 225-3 may be simultaneously formed of the same material in the same process. For example, when the material for forming the fourth-1 common layer 225-1, the fourth-2 common layer 225-2, and the fourth-3 common layer 225-3 is deposited on the entire surface of the substrate 100, a layer formed on the separator SP may be the fourth remaining common layer 225A. For example, the fourth remaining common layer 225A may be formed on the remaining charge generation layer 224a.

The second remaining common layer 227a, the second-1 common layer 227-1, the second-2 common layer 227-2, and the second-3 common layer 227-3 may be simultaneously formed of the same material in the same process. For example, when the material for forming the second-1 common layer 227-1, the second-2 common layer 227-2, and the second-3 common layer 227-3 is deposited on the entire surface of the substrate 100, a layer formed above the separator SP may be the second remaining common layer 227a. For example, the second remaining common layer 227a may be formed on the fourth remaining common layer 225A. The remaining counter electrode 230a, the first counter electrode 230-1, the second counter electrode 230-2, and the third counter electrode 230-3 may be simultaneously formed of the same material in the same process. For example, when the material for forming the first counter electrode 230-1, the second counter electrode 230-2, and the third counter electrode 230-3 is deposited on the entire surface of the substrate 100, a layer formed above the separator SP may be the remaining counter electrode 230a. For example, the remaining counter electrode 230a may be formed on the second remaining common layer 227a.

The separator SP may include an organic insulating material. For example, the separator SP may include BCB, polyimide, HMDSO, PMMA, polystyrene, polymer derivatives having a phenolic group, acrylic polymer, imide-based polymer, aryl ether-based polymer, amide-based polymer, fluorine-based polymer, p-xylene-based polymer, vinyl alcohol-based polymer, mixtures thereof, or the like.

A side surface Spa of the separator SP may include a reversely tapered inclined surface. The side surface SPa of the separator SP including the reversely tapered inclined surface may mean that the width of a portion of the separator SP in a direction opposite to the substrate 100 (+z direction) is greater than the width of a portion of the separator SP in a direction close to the substrate 100 (−z direction). The separator SP having a side surface that is a reversely tapered inclined surface may be formed by using negative photoresist. The photoresist may be classified into positive photoresist and negative photoresist. The positive photoresist may mean photoresist having an increasing solubility to a developer by exposure, and the negative photoresist may mean photoresist having a decreasing solubility to a developer by exposure.

Accordingly, when positive photoresist that is partially exposed is developed, a pattern in which an exposed portion is removed is generated, and when negative photoresist that is partially exposed is developed, a pattern in which a portion that is not exposed is removed is generated. Thus, when a layer on which negative photoresist is applied is exposed by using a mask, not only a portion located below a transmitting portion of the mask, but also a portion adjacent to a lower portion of the transmitting portion, may be exposed. For example, the portion adjacent to the lower portion of the transmitting portion may have a gradually increasing solubility to a developer from an upper end located in a direction close to a light source toward a lower end located in a direction opposite to the light source. Accordingly, the pattern having a reversely tapered inclined surface may be formed.

As the side surface Spa of the separator SP includes a reversely tapered inclined surface, the remaining intermediate layer 220a and the remaining counter electrode 230a may not cover the side surface SPa of the separator SP. Accordingly, the remaining intermediate layer 220a may not be connected to the first intermediate layer 220-1 and the second intermediate layer 220-2, and the remaining counter electrode 230a may not be connected to the first counter electrode 230-1 and second counter electrode. In other words, the remaining intermediate layer 220a may be spaced apart from the first intermediate layer 220-1 and the second intermediate layer 220-2, and the remaining counter electrode 230a may be spaced apart from the first counter electrode 230-1 and second counter electrode. The remaining intermediate layer 220a may not also be connected to the third intermediate layer 220-3, and the remaining counter electrode 230a may not also be connected to the third counter electrode 230-3. In other words, the remaining intermediate layer 220a may be spaced apart from the third intermediate layer 220-3, and the remaining counter electrode 230a may be spaced apart from the third counter electrode 230-3.

Accordingly, the remaining intermediate layer 220a may not be electrically connected to the first intermediate layer 220-1 and the second intermediate layer 220-2, and the remaining counter electrode 230a may not be electrically connected to the first counter electrode 230-1 and second counter electrode. The remaining intermediate layer 220a may not also be electrically connected to the third intermediate layer 220-3, and the remaining counter electrode 230a may not also be electrically connected to the third counter electrode 230-3.

As described above, the first intermediate layer 220-1 of the first organic light-emitting diode OLED1, the second intermediate layer 220-2 of the second organic light-emitting diode OLED2, and the third intermediate layer 220-3 of the third organic light-emitting diode OLED3 may include layers simultaneously formed of the same material in the same process. For example, such layers may be formed by depositing a material for forming the corresponding layers on the entire surface of a substrate. When the separator SP does not exist on the pixel defining layer 215, those layers may be integrally formed in the first organic light-emitting diode OLED1, the second organic light-emitting diode OLED2, and the third organic light-emitting diode OLED3. Accordingly, a leakage current may flow between the first organic light-emitting diode OLED1 and the second organic light-emitting diode OLED2 through those layers.

For example, when a current is supplied only to the first organic light-emitting diode OLED1 that emits green light, a current may be supplied to the second organic light-emitting diode OLED2 via a layer integrally formed with the first-1 common layer 221-1 of the first organic light-emitting diode OLED1, for example, the first-2 common layer 221-2. Alternatively, a current may be supplied to the second organic light-emitting diode OLED2 via a layer integrally formed with the third-1 common layer 223-1, for example, the third-2 common layer 223-2, or a current may be supplied to the second organic light-emitting diode OLED2 via a layer integrally formed with the first charge generation layer 224-1, for example, the second charge generation layer 224-2. Alternatively, a current may be supplied to the second organic light-emitting diode OLED2 via a layer integrally formed with the fourth-1 common layer 225-1, for example, the fourth-2 common layer 225-2, or a current may be supplied to the second organic light-emitting diode OLED2 via a layer integrally formed with the second-1 common layer 227-1, for example, the second-2 common layer 227-2.

As a result, as not only the first organic light-emitting diode OLED1 emits green light, but also the second organic light-emitting diode OLED2 emits red light, display quality may be deteriorated. For example, color purity is lowered. A phenomenon that a current is supplied to the second organic light-emitting diode OLED2 via a layer integrally formed with the first-1 common layer 221-1 of the first organic light-emitting diode OLED1 may also occur in the third organic light-emitting diode OLED3.

However, in the case of the display apparatus 1 according to some embodiments, as described above, the separator SP may be located above the planarization layer 208. Accordingly, even when some of the layers included in the first intermediate layer 220-1, some of the layers included in the second intermediate layer 220-2, and some of the layers included in the third intermediate layer 220-3 are simultaneously formed of the same material in the same process, those layers may not be integrally formed in the first organic light-emitting diode OLED1, the second organic light-emitting diode OLED2, and the third organic light-emitting diode OLED3. In other words, the remaining intermediate layer 220a may be arranged between the first intermediate layer 220-1 and the second intermediate layer 220-2, and the remaining intermediate layer 220a may not be in contact with the first intermediate layer 220-1 and the second intermediate layer 220-2. Accordingly, the first intermediate layer 220-1 and the second intermediate layer 220-2 may be spaced apart from each other.

For example, the first remaining common layer 221a may not be in contact with the first-1 common layer 221-1 and the first-2 common layer 221-2, and the third remaining common layer 223a may not be in contact with the third-1 common layer 223-1 and the third-2 common layer 223-2. The remaining charge generation layer 224a may not be in contact with the first charge generation layer 224-1 and the second charge generation layer 224-2, the fourth remaining common layer 225A may not be in contact with the fourth-1 common layer 225-1 and the fourth-2 common layer 225-2, and the second remaining common layer 227a may not be in contact with the second-1 common layer 227-1 and the second-2 common layer 227-2.

Accordingly, a current may not leak between the first organic light-emitting diode OLED1 and the second organic light-emitting diode OLED2 through those layers. As the separator SP is arranged between the first opening OP1 and the third opening OP3 on a plane, an effect of preventing current leakage between the first organic light- emitting diode OLED1 and the second organic light-emitting diode OLED2 may be obtained between the first organic light-emitting diode OLED1 and the third organic light-emitting diode OLED3.

The connection electrode CNE may be interposed between the pixel defining layer 215 and the separator SP. In other words, the connection electrode CNE may be located on the pixel defining layer 215. Accordingly, the connection electrode CNE may be located on a layer different from the first pixel electrode 210-1, the second pixel electrode 210-2, and the third pixel electrode 210-3. When the connection electrode CNE is located on the same layer as the first pixel electrode 210-1, the second pixel electrode 210-2, and the third pixel electrode 210-3, for example, on the planarization layer 208, an area occupied by the first pixel electrode 210-1, the second pixel electrode 210-2, and/or the third pixel electrode 210-3 may be reduced. Accordingly, the first emission area EA1, the second emission area EA2, and/or the third emission area EA3 may be reduced. However, in the case of the display apparatus 1 according to some embodiments, the connection electrode CNE may be located on a layer different from the first pixel electrode 210-1, the second pixel electrode 210-2, and the third pixel electrode 210-3. Accordingly, the area occupied by the first pixel electrode 210-1, the second pixel electrode 210-2, and/or the third pixel electrode 210-3 may not be reduced. Accordingly, the first emission area EA1, the second emission area EA2, and the third emission area EA3 of desired sizes may be formed.

The connection electrode CNE may include a material different from the materials included in the first pixel electrode 210-1, the second pixel electrode 210-2, and the third pixel electrode 210-3. For example, the connection electrode CNE may include a material having resistance lower than the material included in the first pixel electrode 210-1, the second pixel electrode 210-2, and the third pixel electrode 210-3. For example, the connection electrode CNE may include Cu. As described below, the connection electrode CNE may electrically connect a plurality of counter electrodes to each other, and as the counter electrodes are electrically connected to each other, electrical signals may be effectively transmitted to the counter electrodes via the connection electrode CNE. As the resistance, that is, electrical resistance, of the connection electrode CNE that electrically connect the counter electrodes to each other, is low, the electrical signals may be effectively transmitted to the counter electrodes.

When viewed from the direction perpendicular to the substrate 100 (e.g., in a plan view), the connection electrode CNE may be arranged between the first opening OP1 and the second opening OP2. As described above with reference to FIG. 3, when viewed from the direction perpendicular to the substrate 100 (e.g., in a plan view), the connection electrode CNE may surround by the first opening OP1. Accordingly, when viewed from the direction perpendicular to the substrate 100 (e.g., in a plan view), the connection electrode CNE may also be arranged between the first opening OP1 and the third opening OP3.

The first intermediate layer 220-1 may be located above the connection electrode CNE. For example, the first intermediate layer 220-1 may be located on a part of an upper surface of the connection electrode CNE adjacent to one side surface of the connection electrode CNE. As described above, some of the layers included in the first intermediate layer 220-1, for example, the first-1 common layer 221-1, the third-1 common layer 223-1, the first charge generation layer 224-1, the fourth-1 common layer 225-1, or the second-1 common layer 227-1 may be formed by respectively depositing the materials for forming those layers on the entire surface of the substrate 100. Accordingly, when viewed from the direction perpendicular to the substrate 100 (e.g., in a plan view), the first intermediate layer 220-1 may overlap not only the first pixel electrode 210-1, but also the pixel defining layer 215 and the connection electrode CNE.

The first counter electrode 230-1 may be located above the connection electrode CNE. For example, as the first counter electrode 230-1 may be located on the first intermediate layer 220-1, the first counter electrode 230-1 may be located on a part of the first intermediate layer 220-1 located on the connection electrode CNE. Like some of the layers included in the first intermediate layer 220-1 described above, the first counter electrode 230-1 may be formed by depositing the material for forming the first counter electrode 230-1 on the entire surface of the substrate 100. Accordingly, when viewed from the direction perpendicular to the substrate 100 (e.g., in a plan view), the first counter electrode 230-1 may overlap not only the first pixel electrode 210-1, but also the pixel defining layer 215 and the connection electrode CNE.

The descriptions with respect to the position relation between the connection electrode CNE, and the first intermediate layer 220-1 and the first counter electrode 230-1, may be applied to the position relation between the connection electrode CNE, and the second intermediate layer 220-2 and the second counter electrode 230-2. Also, the descriptions with respect to the position relation between the connection electrode CNE, and the first intermediate layer 220-1 and the first counter electrode 230-1, may be applied to the position relation between the connection electrode CNE, and the third intermediate layer 220-3 and the third counter electrode 230-3. Accordingly, redundant descriptions in this connection are omitted.

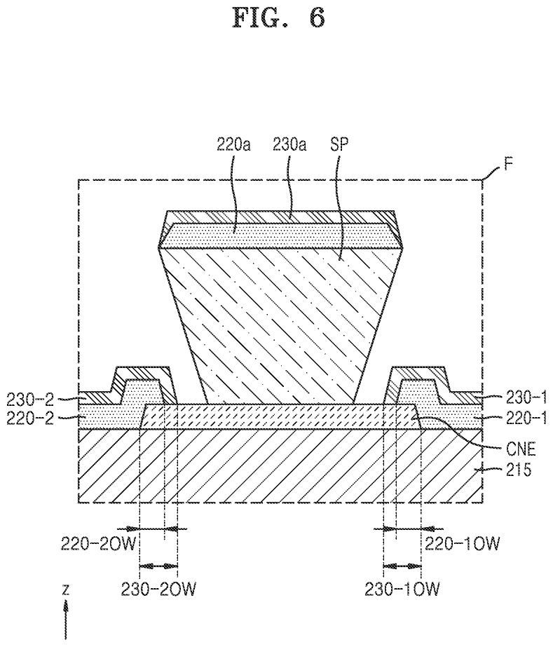

FIG. 6 is a schematic magnified cross-sectional view of a region F of the display apparatus 1 of FIG. 4. As described above, the first intermediate layer 220-1 and the first counter electrode 230-1 may overlap the connection electrode CNE. For example, a part of the connection electrode CNE may be covered by the first intermediate layer 220-1 and/or the first counter electrode 230-1.

When viewed from the direction perpendicular to the substrate 100 (e.g., in a plan view), a width 220-1OW of a portion of the first intermediate layer 220-1 overlapping the connection electrode CNE may be different from a width 230-1OW of a portion of the first counter electrode 230-1 overlapping the connection electrode CNE. As illustrated in FIG. 6, when viewed from the direction perpendicular to the substrate 100 (e.g., in a plan view), the width 220-1OW of the portion of the first intermediate layer 220-1 overlapping the connection electrode CNE may be less than the width 230- of the portion of the first counter electrode 230-1 overlapping the connection electrode CNE. In other words, when viewed from the direction perpendicular to the substrate 100 (e.g., in a plan view), the width 230-1OW of the portion of the first counter electrode 230-1 overlapping the connection electrode CNE may be greater than the width 230-1OW of the portion of the first intermediate layer 220-1 overlapping the connection electrode CNE. Accordingly, even when located on the first intermediate layer 220-1, the first counter electrode 230-1 may be in contact with the connection electrode CNE. Accordingly, the first counter electrode 230-1 may be electrically connected to the connection electrode CNE.

Similarly, when viewed from the direction perpendicular to the substrate 100 (e.g., in a plan view), a width 220-2OW of a portion of the second intermediate layer 220-2 overlapping the connection electrode CNE may be different from a width 230-2OW of a portion of the second counter electrode 230-2 overlapping the connection electrode CNE. As illustrated in FIG. 6, when viewed from the direction perpendicular to the substrate 100 (e.g., in a plan view), the width 220-2OW of the portion of the second intermediate layer 220-2 overlapping the connection electrode CNE may be less than the width 230-2OW of the portion of the second counter electrode 230-2 overlapping the connection electrode CNE. In other words, when viewed from the direction perpendicular to the substrate 100 (e.g., in a plan view), the width 230-2OW of the portion of the second counter electrode 230-2 overlapping the connection electrode CNE may be greater than the width 220-2OW of the portion of the second intermediate layer 220-2 overlapping the connection electrode CNE. Accordingly, even when located on the second intermediate layer 220-2, the second counter electrode 230-2 may be in contact with the connection electrode CNE. Accordingly, the second counter electrode 230-2 may be electrically connected to the connection electrode CNE.

As the descriptions with respect to the width 220-2OW of the portion of the second intermediate layer 220-2 overlapping the connection electrode CNE and the width 230-2OW of the portion of the second counter electrode 230-2 overlapping the connection electrode CNE may be respectively applied to the width of a portion of the third intermediate layer 220-3 overlapping the connection electrode CNE and the width of a portion of the third counter electrode 230-3 overlapping the connection electrode CNE, redundant descriptions in this connection are omitted.

Generally, as the counter electrodes included in the display elements are integrally formed across the entire surface of the display area DA, the counter electrodes included in the display elements may be electrically connected to each other. The same electrical signal may be supplied to the display elements through the counter electrodes that are integrally formed. For example, the same electrode power voltage ELVSS may be supplied to the display element through the counter electrodes that are integrally formed. Accordingly, the counter electrodes that are integrally formed may serve as a wiring for supplying the electrode power voltage ELVSS to the display elements.

When the layers commonly provided in the intermediate layers included in the display elements are cut off or separated from each other by using the separator SP, the counter electrodes included in the display elements may be cut off or separated from each other. Accordingly, the counter electrodes included in the display elements may not be electrically connected to each other.

However, the display apparatus 1 according to one or more embodiments may include the connection electrode CNE that is electrically connected to the first counter electrode 230-1 and the second counter electrode 230-2. In other words, as the counter electrodes included in the display elements are electrically connected to the connection electrode CNE, the counter electrodes included in the display elements may be electrically connected to each other. Accordingly, in the case of the display apparatus 1 according to one or more embodiments, even when the layers commonly provided in the intermediate layers included in the display elements are cut off or separated from each other by using the separator SP, the counter electrodes included in the display elements may be electrically connected to each other. Accordingly, the electrical signals may be effectively transmitted to the counter electrodes.

Furthermore, in the case of the display apparatus 1 according to one or more embodiments, the connection electrode CNE may surround the counter electrodes. For example, while located on the pixel defining layer 215, the connection electrode CNE may surround, on a plane, a plurality of openings included in the pixel defining layer 215. The counter electrodes may be located in the openings. The counter electrodes may be located not only in the openings, but also on the pixel defining layer 215 and the connection electrode CNE. For example, a plurality of holes included in the connection electrode CNE having a mesh structure, for example, the first connection electrode hole CNEH1, the second connection electrode hole CNEH2, and the third connection electrode hole CNEH3 may be filled by a plurality of counter electrodes, for example, the first counter electrode 230-1, the second counter electrode 230-2, and the third counter electrode 230-3. This may have the same effect as in the case in which the counter electrodes included in the display elements are not cut off or separated from each other. Accordingly, the electrical signals may be effectively transmitted to the counter electrodes.

As the organic light-emitting diode OLEDS may be easily damaged by external moisture, oxygen, or the like, the organic light-emitting diode OLEDS may be protected by covering the organic light-emitting diode OLEDS with an encapsulation layer. The encapsulation layer may include a first inorganic encapsulation layer, an organic encapsulation layer, and a second inorganic encapsulation layer, and cover the display area DA and extend to the outside of the display area DA.

As described above, according to one or more embodiments described as above, a display apparatus may be implemented which may reduce a leakage current and also relatively effectively transmit electrical signals to a plurality of counter electrodes. The scope of embodiments according to the present disclosure is not limited by the effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and their equivalents.

What is claimed is:

1. A display apparatus comprising:
a first pixel electrode and a second pixel electrode spaced apart from each other on a substrate;
a pixel defining layer having a first opening exposing a central portion of the first pixel electrode and a second opening exposing a central portion of the second pixel electrode;
a separator above the pixel defining layer and, in a plan view, between the first opening and the second opening;
a connection electrode between the pixel defining layer and the separator;
a first intermediate layer on the first pixel electrode;
a second intermediate layer on the second pixel electrode and spaced apart from the first intermediate layer;
a first counter electrode on the first intermediate layer and electrically connected to the connection electrode; and
a second counter electrode on the second intermediate layer, spaced apart from the first counter electrode, and electrically connected to the connection electrode.

2. The display apparatus of claim 1, wherein, in the plan view, a width of a portion of the first counter electrode overlapping the connection electrode is greater than a width of a portion of the first intermediate layer overlapping the connection electrode.

3. The display apparatus of claim 2, wherein the connection electrode is in contact with the first counter electrode.

4. The display apparatus of claim 3, wherein, in the plan view, a width of a portion of the second counter electrode overlapping the connection electrode is greater than a width of a portion of the second intermediate layer overlapping the connection electrode.

5. The display apparatus of claim 4, wherein the connection electrode is in contact with the second counter electrode.

6. The display apparatus of claim 1, further comprising a remaining counter electrode on the separator.

7. The display apparatus of claim 6, wherein the first counter electrode, the second counter electrode, and the remaining counter electrode comprise a same material.

8. The display apparatus of claim 6, further comprising a remaining intermediate layer between the separator and the remaining counter electrode.

9. The display apparatus of claim 8, wherein the first intermediate layer, the second intermediate layer, and the remaining intermediate layer comprise a same material.

10. The display apparatus of claim 1, wherein the connection electrode comprises a material different from the first pixel electrode and the second pixel electrode.

11. The display apparatus of claim 10, wherein the connection electrode comprises a material having a resistance lower than a material included in the first pixel electrode and the second pixel electrode.

12. The display apparatus of claim 1, wherein, in the plan view, the separator surrounds the first opening and the second opening.

13. The display apparatus of claim 12, wherein, in the plan view, the connection electrode surrounds the first opening and the second opening.

14. The display apparatus of claim 1, wherein a side surface of the separator includes a reversely tapered inclined surface.

15. The display apparatus of claim 14, further comprising a remaining counter electrode on the separator, wherein the remaining counter electrode does not cover the side surface of the separator.

16. The display apparatus of claim 15, wherein the remaining counter electrode is spaced apart from the first counter electrode and the second counter electrode.

17. The display apparatus of claim 16, wherein the remaining counter electrode is not electrically connected to the first counter electrode and the second counter electrode.

18. The display apparatus of claim 15, further comprising a remaining intermediate layer between the separator and the remaining counter electrode,
wherein the remaining intermediate layer does not cover the side surface of the separator.

19. The display apparatus of claim 18, wherein the remaining intermediate layer is spaced apart from the first intermediate layer and the second intermediate layer.

20. The display apparatus of claim 19, wherein the remaining intermediate layer is not electrically connected to the first intermediate layer and the second intermediate layer.
